(19) United States
(12) Patent Application Publication
(10) Pub. No.: US 2022/0289938 A1
(43) Pub. Date: Sep. 15, 2022

(54) A MICROSTRUCTURED FILM COMPRISING INORGANIC-ORGANIC HYBRID POLYMERS, A METHOD FOR MANUFACTURING THEREOF AND A METHOD FOR COOLING A SUBSTRATE BY APPLYING SAID MICROSTRUCTURED FILM

(71) Applicants: FUNDACIO INSTITUT CATALA DE NANOCIENCIA I NANOTECNOLOGIA, Ballaterra (ES); INSTITUCIÓ CATALANA DE RECERCA I ESTUDIS AVANÇATS, Barcelona (ES)

(72) Inventors: Juliana Jaramillo Fernández, Barcelona (ES); Nikolaos Kehagias, Thessaloniki (GR); Achille Francone, Barcelona (ES); Clivia Marfa Sotomayor Torres, Velbert (DE)

(73) Assignee: INSTITUCIÓ CATALANA DE RECERCA I ESTUDIS AVANÇATS, Barcelona (ES)

(21) Appl. No.: 17/597,936

(22) PCT Filed: Jul. 30, 2020
(86) PCT No.: PCT/EP2020/071560

§ 371 Date: Jan. 28, 2022

(30) Foreign Application Priority Data
Jul. 30, 2019 (EP) 19382655.9

(51) Int. Cl. C08K 3/34; B82Y 40/00; G03F 7/00

(52) U.S. Cl. CPC C08K 3/34; B82Y 40/00; G03F 7/0002

(57) ABSTRACT

A microstructured film that includes inorganic-organic hybrid polymers over a substrate is disclosed. Also disclosed are a method for manufacturing said microstructured film, a method for cooling the surface of a substrate including the step of applying said microstructured film, and a substrate that includes said microstructured film.

### CROSS-REFERENCE TO RELATED APPLICATIONS

This application is a Section 371 National Stage Application of International Application No. PCT/EP2020/071560, filed on Jul. 30, 2020, entitled “A MICROSTRUCTURED FILM COMPRISING INORGANIC-ORGANIC HYBRID POLYMERS, A METHOD FOR MANUFACTURING THEREOF AND A METHOD FOR COOLING A SUBSTRATE BY APPLYING SAID MICROSTRUCTURED FILM”, which claims priority to European Application No. 19382655.9, filed Jul. 30, 2019, which is incorporated herein by reference in its entirety.

### TECHNICAL FIELD

The present disclosure relates to a microstructured film comprising an inorganic-organic hybrid polymer which is capable to cool down and to keep clean the surface on which it is applied on.

The present disclosure further relates to a method for manufacturing said microstructured film and to a method for cooling the surface of a substrate by applying said microstructured film.

### BACKGROUND

The phenomenon of radiative cooling, and in particular using the coldness of space for terrestrial thermal management is not new [1-4], yet it was not until very recently that daytime passive cooling was achieved for a silicon (Si) absorber using a visibly transparent broadband thermal blackbody [5]. This particular thermal management solution consists of a periodic silica photonic structure. When placed on a Si absorber under sunlight, it preserves absorption of visible wavelengths while reducing the device temperature by as much as 17% due to radiative cooling.

Since then, other designs including photolithography-based photonic microstructured surfaces [6-8], polar multi-layered structures [6, 9], coatings [10, 11] and polar-polymer metamaterials on metal mirrors have been proposed [12, 13]. Very recently, a glass-polymer hybrid 80 μm-thick structure composed of randomly positioned silica spheres encapsulated by a transparent polymer has achieved a 93 W/m² cooling power density under direct sunlight [13]. Its high infrared emissivity is attributed to phonon-enhanced Frohlich resonances of the microspheres. Other groups have demonstrated temperature drops of 8 K with very simple PDMS on quartz structures, corresponding to a radiative cooling power of 127 W/m² [14].

The phenomenon of superhydrophobicity [15, 16] observed in nature includes the interaction of water with the surfaces of various plants [17] and insects [18], thus attracting researchers attention over the last years. A superhydrophobic surface generally exhibits extremely high water repellency and is characterised by a water contact angle >150° and a small hysteresis angle <15°. The most famous case for this natural effect is represented by the lotus leave were water droplets roll-off while dust particles are removed from the leafs surface, resulting in the so-called self-cleaning effect (also known as “lotus” effect). Intensive research efforts have been placed over the last years to produce self-cleaning surfaces [19, 20].

### SUMMARY

In a first aspect, the present disclosure relates to a microstructured film comprising or consisting of or consisting essentially of inorganic-organic hybrid polymers.

In a second aspect, the present disclosure relates to a method for manufacturing a microstructured film according to the first aspect of the disclosure.

In a third aspect, the present disclosure relates to a method for cooling a substrate or the surface of a substrate comprising the step of applying the microstructured film according to the first aspect of the disclosure.

In a fourth aspect, the present dislcosure relates to a substrate comprising the microstructured film according to the first aspect of the disclosure.

### BRIEF DESCRIPTION OF THE DRAWINGS

FIG. 1: Cross section schematics of exemplary structures with some encompassed by the present disclosure.

FIG. 2: Periodic pattern consisting of a plurality of structures encompassed by the present disclosure on a substrate (using Ormocomp® as the polymer and Si as the substrate).

FIG. 3: Schematic flow showing the fabrication process for the microstructured film.

FIG. 4: (a) The solar irradiance A.M 1.5 (reference spectrum at mid-latitudes with an air mass coefficient of 1.5) [21] and the atmosphere transmission calculated for Barcelona with MODTRAN (b) Spectral response of an ideal broadband radiator (continuous line), reflecting or transmitting visible and near-IR light up to 2.5 μm and re-emitting as a blackbody in the infrared spectral range. The terrestrial blackbody irradiance (at 300K) is also plotted for comparison. (c) Emissivity spectra of bulk Si and Si covered with the microstructured film. (d) Net radiative cooling power density calculated for a perfect broadband radiator considering relative temperatures between the ambient, Ta, and the radiator surface, Tr, from −60 to 30 K.

FIG. 5: Schematic representation of the radiative cooling working principle in the microstructured film used for radiative cooling. a) Thermal excitation of SPhP. Localized resonant coupling between photons and collective oscillations of dipoles. b) Heat is radiated as thermal energy due to the enhanced emissivity resulting from the gradual change in shape and the diffraction of surface phonon polaritons via the two-dimensional (2D) grating.

FIG. 6: a) Experimental set-up for continuous temperature measurements of a bare Si substrate, an unpatterned reference on Si and a patterned film with mushroom like structures on Si. b) Schematic illustrations of the studied samples.

FIG. 7: a) Schematics of the studied samples. b) Measured cycle of temperature during 44 hours in a clear-sky day for the bare Si substrate, the unpatterned reference on Si, and the mushroom-type microstructured layer on Si. The evolution of the ambient temperature is plotted as a grey dotted line for reference. c) Temperature difference between the bare Si and the microstructured cooler, as well as the unpatterned reference.

FIG. 8: a) Schematics of the studied samples backed with a silver mirror to reflect the visible light. b) Measured cycle of temperature during 24 hours in a clear-sky day for the bare Si substrate, the unpatterned reference on silver coated Si, and the mushroom-type microstructured layer on silver coated Si. The evolution of the ambient temperature is plotted as a grey dotted line for reference. c) Temperature difference between the bare Si and the microstructured cooler, as well as the unpatterned reference. The temperature difference between the ambient and the microstructured cooler, as well as the unpatterned reference is ploted as well.

FIG. 9: Figure according to Example 3. a) Measured cycle of temperature for the bare Cu (bCu) and covered Cu (RCCu) in relation to the outdoor temperature (Tout), from the 6^{th} to 14th of March, under diverse environmental conditions. B) Temperature difference between the bare Cu (bCu) and covered Cu (RCCu).

FIG. 10: Figure according to Example 4. a) temperature and c) voltage measurements for the six cells previous to the RC film adhesion, respectively. b) and d) are temperature and voltage measurements for the covered cell and the other five references. The darker lines show the cell that was later covered with the RC film. The other five references are plotted as a mean with a standard deviation of the values in time.

FIG. 11: Measured cycle of temperature from 9 AM to 4:30 PM during a clear-sky day for the bare Si substrate, the unpatterned reference on Si, and the mushroom-type microstructured layer on Si with different dimensions. Dimensions of 4 um diameter/4 um height correspond to sample 100A, 6 um diameter/4 um height to sample 100B, 2 um diameter/2 um to sample 106B respectively. The evolution of the ambient temperature is with scattered star symbols. The relative humidity is a grey thick continuous line.

FIG. 12: Picture showing the dew on a non-covered solar cell and the covered solar cell without dew formation.

### DETAILED DESCRIPTION

The present disclosure relates to a microstructured film comprising an inorganic-organic hybrid polymer which is capable to cool down and to keep clean the surface on which it is applied on, in particular an exterior surface. Indeed, the present inventors have surprisingly found that this microstructured film has a dual functionality and has been proved to have a passive radiative cooling and self-cleaning properties.

Accordingly, in a first aspect of the present disclosure a microstructured film (sometimes herein mentioned simply as film) comprises, consists of or consists essentially of inorganic-organic hybrid polymers, wherein the structure thereof is composed by repetitive elements having each one of the following shapes:

I) a shape which vertical cross-section is in the form of a 4-sided polygon in which the upper side and the lower side are parallel and have a different length;

II) a shape which vertical cross-section is a concave plane;

III) a shape which vertical cross-section is in the form of a 4-sided polygon in which the upper side and the lower side are parallel and have a different length (also mentioned herein as “mushroom” like structure),

and wherein the length of the lower side for shapes I) and III), or the length of the flat part of the concave plane in shape II) ranges from 0.1 μm to 100 μm, preferably from 0.1 μm to 50 μm and more preferably from 0.1 μm to 20 μm,

and wherein the distance between each element in the film (being in a flat, uncompressed and unstretched configuration) ranges from 1 μm to 100 μm, preferably from 1 μm to 50 μm and more preferably from 1 μm to 20 μm,

and wherein the height of each element is lower than 100 μm, preferably lower than 20 μm, more preferably lower than 7 μm.

Preferably, the aspect ratio of the structures is from 0.5 to 3 and more preferably about 1.5. The aspect ratio is defined as the width of the structure divided by the height of the structure.

In the context of the present disclosure, the term “comprising” refers to a composition, compound, formulation, or method that is inclusive and does not exclude additional elements or method steps. The term “comprising” also refers to a composition, compound, formulation, or method embodiments of the present disclosure that is inclusive and does not exclude additional elements or method steps.

In the context of the present disclosure, the term “consisting of” refers to a compound, composition, formulation, or method that excludes the presence of any additional component or method steps. The term “consisting of” also refers to a compound, composition, formulation, or method of the present disclosure that excludes the presence of any additional component or method steps.

In the context of the present disclosure, the term “consisting essentially of” refers to a composition, compound, formulation or method that is inclusive of additional elements or method steps that do not materially affect the characteristic(s) of the composition, compound, formulation or method. The term “consisting essentially of” also refers to a composition, compound, formulation or method of the present disclosure that is inclusive of additional elements or method steps that do not materially affect the characteristic(s) of the composition, compound, formulation, or method.

It is noted that the parameters of “length”, “distance” or “height” according to their values and as used in the definition of the microstructured film according to the first aspect of the disclosure, can be combined irrespective of each other, i.e., by way of example, the more preferred option for the length (from 0.1 μm to 20 μm) can be combined with a distance between each element in the film between 1 μm and 100 μm and a height of each element lower than 100 μm, or any other of the possible combinations between the optimal options and non-optimal options.

In another embodiment, the microstructured film according to the first aspect of the present disclosure comprising, consisting of or consisting essentially of inorganic-organic hybrid polymers is deposited over a carrier as a mechanical support. Preferably, said carrier is a transparent polymer. Examples of said polymer are polymethylpentene, polyethylene (HDPE, LDPE) or polyethylene terephthalate, but examples of said polymer are not limited thereto.

In a preferred embodiment, the microstructured film according to the first aspect of the present disclosure comprising, consisting of or consisting essentially of inorganic-organic hybrid polymers comprises, consists of, consists essentially of or is derived from inorganic silicates with Si—O—Si linkages. In a more preferred embodiment, said inorganic silicates with Si—O—Si linkages are Polyhedral Oligomeric SilSesquioxanes (POSS) or Organically Modified Ceramics. In an even more preferred embodiment, said inorganic-organic hybrid polymer which comprises, consists of, consists essentially of or derives from Organically Modified Ceramics is ORMOCOMP®.

In the context of the present disclosure, the term “derives from” or “is derived from” means that the subsequent mentioned material has been subjected to any physical or chemical treatment in order to obtain the final material to be used according to an established purpose.

In the present disclosure, Organically Modified Ceramics are defined as hybrid polymers with inorganic and organic moieties linked by stable covalent bonds and based on organically modified alkoxysilanes, functionalized organic polymers or both.

Organically Modified Ceramics (sometimes also called ORMOCER®) can also be defined as inorganic-organic hybrid polymers which are synthesized in a first step by sol-gel processing. By catalytically controlled hydrolysis/polycondensation of organically modified (R′x) metal alkoxides, e. g. R′xSi(OR)4-x, a partially inorganic network is built up by the formation of organically functionalized inorganic-oxidic oligomers (sol/resin). In a second step, these can be thermally and/or photochemically (UV) cross-linked due to the organic functionalities R′x, whereas R′x can be a styryl-, methacryl-, acryl- and/or an epoxy-group. Finally, after thermal curing of the functional layers, microstructures or bulk materials are obtained (Frauenhofer Institute for Silicate Research (ISC), Würzburg, Germany) See https://www.isc.fraunhofer.de/content/dam/isc/de/documents/Publikationen/Inorganic-organic_hybrid_polymers_ORMOCER_for_micro_systems_technology.pdf)

OrmoComp® is a hybrid organic-inorganic polymer synthesized during sol-gel process and depends on ORMOCER® material class. The backbone thereof is made up of an inorganic silicate network ≡Si—O—Si≡ with single bonds between atoms. Organo(alkoxy)silanes are used as an organic crosslinking units in order to functionalize material with polymerizable groups, namely methacryloxy group [21].

In a second aspect, the present disclosure relates to a method for manufacturing a microstructured film as defined in any of the previous embodiments , comprising the steps of:

a) contacting an inorganic-organic hybrid polymer with polydimethylsiloxane acting as a working stamp;

b) applying low pressure between 1 and 5 bar over the assembly obtained in step a) and exposing it to UV light for curing;

c) separating the polydimethylsiloxane from the cured inorganic-organic hybrid polymer, giving thereby the microstructured film.

In a preferred embodiment, said method for manufacturing a microstructured film further comprises, before step a), the step of putting into contact putting into contact a carrier as previously defined to said inorganic-organic hybrid polymer.

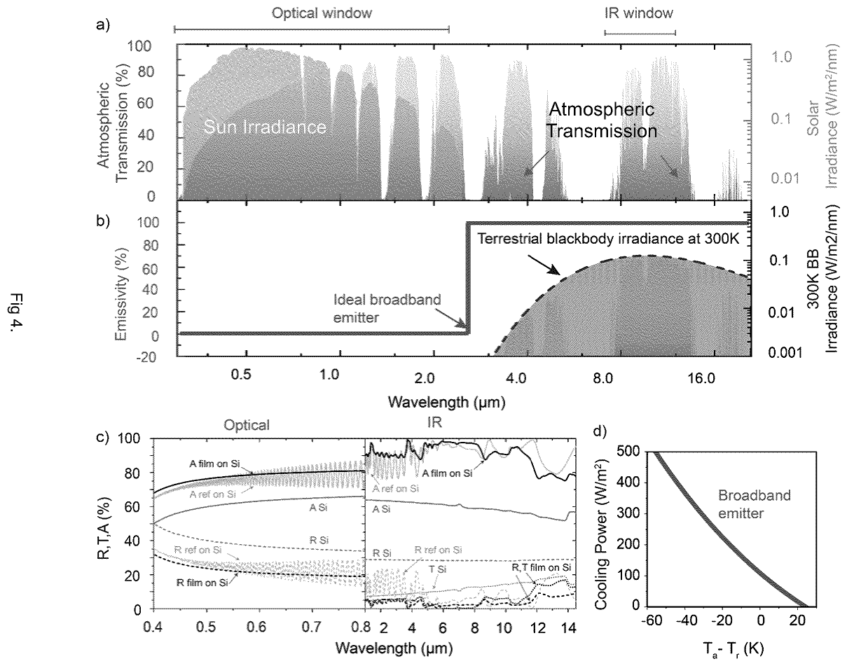

In particular, the microstructured film according to the present disclosure is fabricated using a method, namely ultraviolet light assisted nanoimprint lithography (UVNIL). FIG. 3 schematically shows the fabrication process.

In a preferred embodiment, the inorganic-organic hybrid polymers comprises, consists of, consists essentially of or derives from inorganic silicates with Si—O—Si linkages. In a more preferred embodiment, said inorganic silicates with Si—O—Si linkages are Polyhedral Oligomeric SilSesquioxanes (POSS) or Organically Modified Ceramics as previously defined In an even more preferred embodiment, said inorganic-organic hybrid polymer comprises, consists of, consists essentially of or derives from Organically Modified CERamics (ORMOCER®) is ORMOCOMP®.

In step a), the inorganic-organic hybrid polymer is contacted with polydimethylsiloxane which contains a negative polarity of the structures to be fabricated and is used as a working stamp.

After that step, a low pressure is applied (between 1 and 5 bar, preferably, between 1 and 3 bar) to ensure that the polymer can uniformly spread and fill the working stamp cavities. The assembly is then exposed to UV light for few seconds for curing (for example 3-5 sec) and finally in a further step the assembly is detached.

The present inventors have also surprisingly found that the microstructured films as defined in the first aspect of the disclosure have a dual functionality of radiative cooling and self-cleaning.

Accordingly, they have surprisingly found that these microstructured films could be adapted and integrated directly on a surface which requires cooling and/or as a large area adhesive film on a surface which requires this dual functionality: to be cool down and kept clean.

In a third aspect, the present disclosure relates to a method for cooling the surface of a substrate, which can be flexible or rigid, comprising the step of applying the microstructured film, with or without carrier, according to any of the embodiments of the first aspect of the disclosure, over said substrate, wherein the substrate is any material that suffers from heating and needs to be cooled down passively, by applying the film. This definition of “substrate” or “surface of a substrate” is applied hereinabove or hereinafter. Preferably, said substrate is selected from a metallic surface, silicon, solar cells, structural materials used in roofs and buildings, polymers or glass.

In the case in that the microstructured film is without carrier, this is directly applied over said substrate, wherein the film is then in direct contact with the substrate.

In the case in that the microstructured film is with carrier, this is applied over said substrate by means of a natural or synthetic adhesive, optionally with a physical curing (such as drying, pressure sensitive, contact or hot adhesives) or chemical curing (such as anaerobic, multi-part, pre-mixed and frozen and one-part adhesives), wherein the adhesive is applied between the carrier and the substrate. When a carrier is requested, the inorganic-organic hybrid polymer is first applied and cured over the carrier.

The substrate is usually cleaned and dried before the application of the film with or without carrier. For example, a Si substrate is preferably used. This substrate is usually cleaned in IPA (isopropyl alcohol) and acetone and dried for 5 min on a hot plat at 150° C.

In a further preferred embodiment, said substrate is located outdoors, in particular facing the sky and receiving the sunlight. In a further preferred embodiment, said substrate is located in traffic and mobility monitoring devices, agriculture irrigation controllers, glass or plastic greenhouse, windows, building facets, building windows, automotive windows, transport, outdoor lightning, photovoltaic panels, solar panels, displays, eye glasses, airplane wings, radio-antennas, signal processing equipment, military equipment, textile clothing, thermoelectric generators units, air-conditioning units, refrigeration-units, portable vaccine coolers, medical-transport space-crafts, space instrumentation systems, nuclear-engines.

Advantageously, by applying the microstructured film of the present disclosure over the surface of a substrate as defined above, this surface is cooled down radiatively, without the use of electricity or any other means of added external energy input, due to the fact that is a passive mechanism and therefore implies no energy cost. Radiative cooling works by emitting longwave radiation through the infrared atmospheric window using outer space as a cold reservoir or heat sink.

The radiative cooling functionality is achieved due to the optical properties of the microstructured film as defined herein, obtained by the topography given to the film using imprint lithography process. The optical properties of the film are a negligible absorptivity in the visible wavelength range (from 400 nm to 900 nm), and a nearly unity emissivity beyond 2.5 μm until at least 26 μm. Due to these optical characteristics, related to the patterns/the topology given to the microstructured film by means of the imprinting lithography process, thermal energy is radiated more effectively from the film, compared to the case where the polymer layer is unpatterned. The portion of the IR radiation, emitted from the film in the wavelength range that matches the transparency of the IR atmospheric window (from 8 to 13 μm), passes throughout the atmosphere without being absorbed, exchanging heat directly with the outer cold space that is at a temperature of 3K. Such exchange that takes place through the IR atmospheric window due to its negligible absorption in the wavelength range from 8 μm to 13 μm, then results in cooling down the surface below said film. The portion of the IR radiation outside 8-13 μm is exchanged with the sky, which is at lower temperature than the mentioned surface, resulting also in cooling. This cooling process may happen as well during daytime, thanks to the low absorption of the film in the visible range, which inhibits the heating of the patterned film due to direct incidence of sunlight, while simultaneously radiating heat at the thermal wavelengths and therefore achieving cooling passively. To illustrate this, FIG. 4a shows, the atmospheric transmission and the solar irradiance (1.5 A.M spectral reference [22]). Since the microstructured film does not heat up due to sunlight absorption, the heat coming from an element or surface below the microstructured film can be evacuated by radiation to the outer space as infrared thermal energy in the range between 8 μm to 13 μm (IR window) in amounts proportional to T⁴, thus being a process very sensitive to the temperature.

The microstructured film acts as a nearly-ideal infrared broadband emitter, while preserving a high transmittance (low absorption) to visible light. Radiative cooling of the underlying surface due to the microstructured film deposited on it is achieved because the outgoing radiated energy per unit time is greater than the incoming energy from the atmosphere and the sun. For the sake of clarity, the spectral response of an ideal broadband infrared emitter is depicted in FIG. 4b, showing nearly perfect emissivity over the full infrared spectrum, from 2.5 to 26 μm. The microstructuration of the film provides an emissivity response shown in FIG. 4c by way of example, but not by way of limitation, that may resemble closely an ideal infrared blackbody (continuous line in FIG. 4b). The corresponding net radiative cooling power, Pₙₑₜ, of a surface with such optical properties at an operating temperature Tᵣ can be calculated as the sum of incoming and outgoing energy per unit time in the system [23]:

Pₙₑₜ(Tᵣ, Tₐ)=Pᵣ(Tᵣ)−Pₐ(Tₐ)−Pₛᵤₙ−P_{non-rad}(Tᵣ, Tₐ) (1)

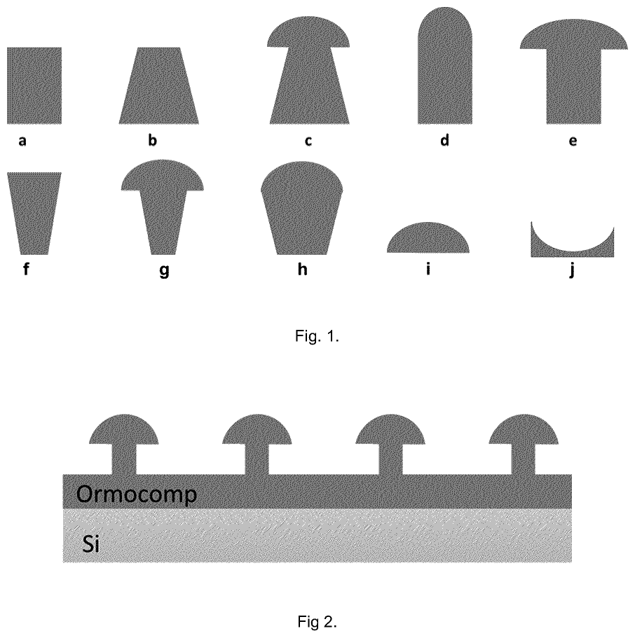

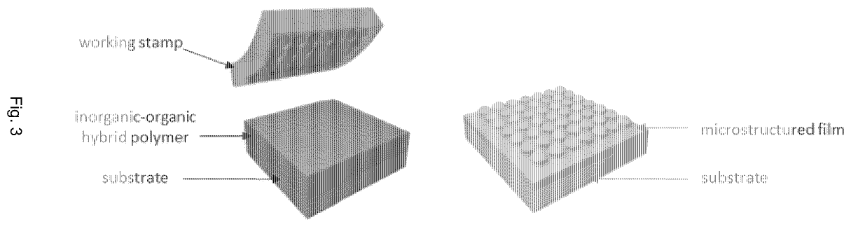

The effective radiative cooling power density calculated for an ideal broadband infrared radiator as a function of the relative temperature between the ambient, Tₐ, and the radiator, Tᵣ is plotted in FIG. 1d, showing that a power density up to 400 W/m² can be evacuated to the outer space at Tₐ−Tᵣ=−40. This represents, for example, about 35% of the power dissipated as heat by a solar cell. Passively removing this amount of heat would translate into a relative efficiency increase up to 10%, since solar cell efficiency is reduced by 0.5% for every degree of temperature increase [24].

The working principle of radiative cooling via the disclosed herein microstructured film is explained as follows. The material used to fabricate the film is an inorganic-organic hybrid polymer, which is synthesized during sol-gel process and its back-bone is preferably formed from inorganic silicate Si—O—Si linkages. This type of UV curable polymer has glass-type material properties after UV curing, exhibiting highly transmittance near the ultraviolet and the visible wavelengths. Glass is mainly made of silica (SiO₂), which is a polar material, exhibiting a non-vanishing dipole moment. As a consequence, the electromagnetic radiation interacts with the dipoles of the ionic polar material. Bulk silica exhibits emissivity dips at around 8 um and 20 um, arising from the interaction of optical phonons and electromagnetic radiation, so-called bulk phonon-polariton resonances, which result in high reflectivity (low emissivity) spectral regions, something detrimental for radiative cooling. These emissivity dips which reduce the radiative cooling, can be suppressed by engineering the material surface, which allow us to modify the interaction between electromagnetic radiation and the collective mechanical oscillations of the dipoles at the surface of the glass-like material to enhance the emissivity, in contrast to the emissivity dips that are characteristic of the unpatterned polar material. The patterning of the disclosed herein structures on the film results in decreased reflectivity and achieves an ultrahigh nearly-unity emissivity throughout all the IR wavelengths up to 26 μm, enabling optimum radiative heat exchange, between the hot underlying substrate and the outer space, through the atmosphere. This, allows the heat coming from the substrate to be deposited in the outer space that acts as a big very cold heat sink.

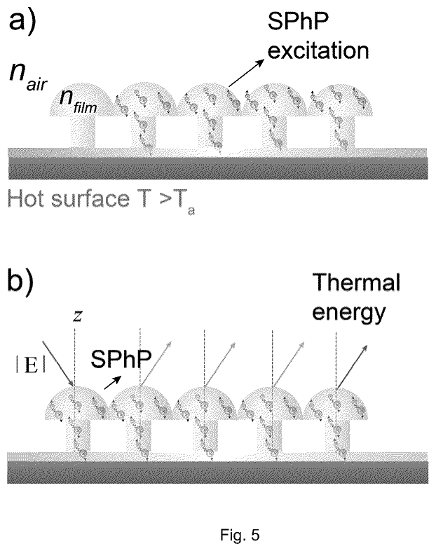

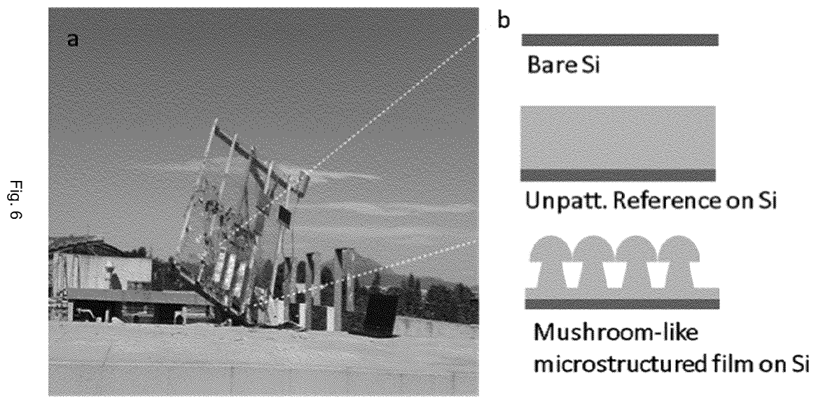

The ultra-high infrared emissivity (beyond 2.5 μm) is achieved by combining three effects (illustrated in FIG. 5) that result from the topography and the dielectric response of the glass-like material: i) the upper shape of the microstructure, ii) the thermal excitation of localized hybrid surface modes, i.e., surface phonon polaritons (SPhP) and iii) the diffraction of such excitations to the far field via the periodic lattice induced by the patterning, as explained in detail below

The differential polar-dielectric boundaries from the hemispheres result in a progressive variation of the material effective refractive index, n_{eff}=c/dk/dw, which is a function of wavelength and hemisphere radius, with w and k being the energy and the wavevector of the photons [25]. This yields an impedance matching between the polar and the dielectric media (silica/air) over a large spectral range [26].

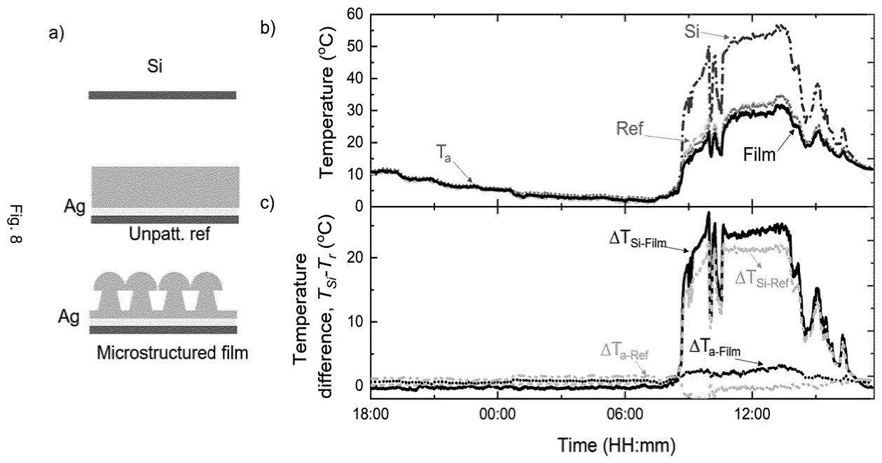

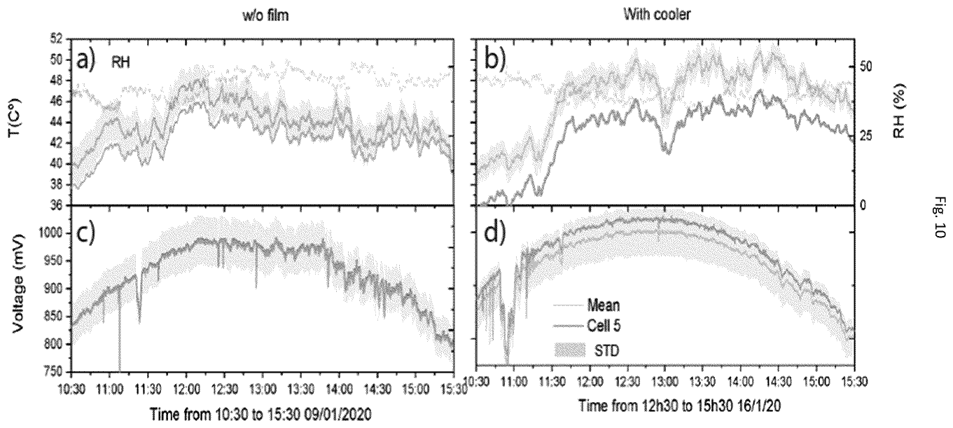

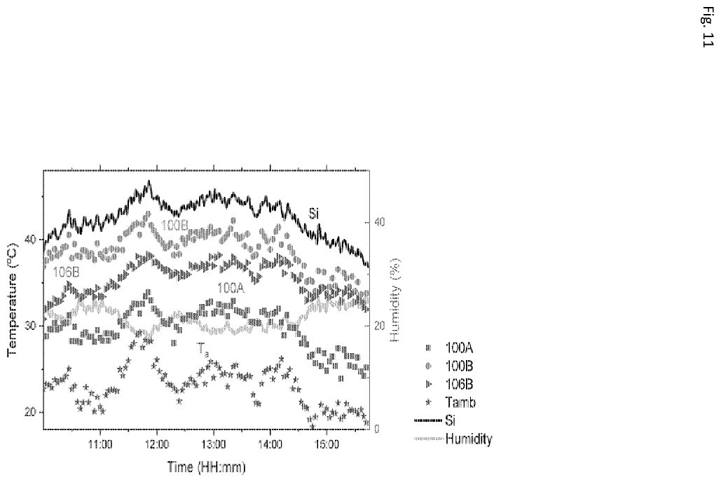

The undesired temperature rise generated by dissipation in the underlying substrate i.e a Si wafer acting as a solar absorber (Example 1, FIG. 7) or Cu slab (Example 3, FIG. 9), or a solar cell (Example 4, FIG. 10), becomes a heat source to activate localized SPhP resonances in the polar hemispheres. SPhP are collective mechanical oscillations of the dipoles in the polar hemisphere that interact resonantly with photons of the same frequency. At the surface, this results in an evanescent field with high intensity and strong near field confinement. However, the effect of this surface modes is not transmitted in the far field [27, 28].

By ruling a grating with period d on the interface between the polar and the dielectric media, SPhP can be outcoupled into the far-field, resulting in enhanced emissivity. Such SPhP-mediated emissivity depends on the polarization and the azimuth angle θ, according to:

$$\frac{2 π}{λ} sin θ = {\vec{q}}_{x} + n \frac{ 2 π}{d} \qquad ( 2 )$$

Where qₓ is the wavevector of the surface excitation and n is an integer. The microstructured film acts as a grating in two dimensions, where the patterned periodicity diffracts the SPhPs into the far field, thus further enhancing the emissivity, even at high incident angles.

In this way, the heat dissipated by the surface to be cooled is evacuated as thermal radiation optimised to pass through the transparent infrared atmospheric window via surface engineering.

It is important to clarify that the underlying substrate on which the cooling film is deposited and then microstructured by imprinting lithography could be of any nature. The only specific condition for achieving cooling of this substrate is that its surface should be at a temperature higher than the ambient temperature. Usually substrates where the microstructured film could solve heating issues are substrates that undergo critical heating and have high operating temperatures above the ambient, which results in drastic effects on performance. This means that any material that suffers from heating and needs to be cooled down passively by applying the microstructured film meets the conditions for benefiting from passive radiative cooling provided by the microstructured film. Examples of these materials are metallic surfaces, silicon, solar cells, structural materials used in roofs and buildings, polymers or glass. In the text, we refer to Si often, because is the textbook material used in several references to demonstrate passive cooling of it by a cooling film. ^{1,2,3,4}.

The other two specific conditions mentioned to achieve optimum radiative cooling performance are: the upper shape of the microstructure as well as the period and the dimensions of the patterns imprinted in the polymer film, which define the grating that serves to outcouple the resonant hybrids modes, enabling ultrahigh emissivity of our film.

The dielectric constant of glass-like polymer layer to be microstrutured exhibits phonon polaritons resonances in the infrared region, which generally leads to suboptimal emissivity in the IR. By producing a two-dimensional grating via microimprint lithography on the glass-like polymer layer, surface modes can be excited and diffracted. This physical mechanism, which strongly depends on the size of the micropattern that forms the grating structure, results in nearly perfect thermal emission for a wide range of thermal wavelengths. The enhanced emissivity and thus optimal radiative cooling heavily depend on the pattern dimensions. This dependence is evidenced by the steady state temperature measurements for microstructured films with different dimensions, shown in FIG. 11.

From FIG. 11, it can be seen that the film patterned with 4 um diameter and 4 um height features keeps the Si cooler than the other samples, patterned with structures of different dimensions.

In a fourth aspect, the present disclosure relates to a susbtrate comprising the microstructured film according to the first aspect of the disclosure in any of the disclosed embodiments, alone or in combination. In a preferred embodiment, said substrate is located outdoors, in particular facing the sky and directly receiving the sunlight. In a more preferred embodiment, said substrate is located in traffic and mobility monitoring devices, agriculture irrigation controllers, glass or plastic greenhouse, windows, building facets, building windows, automotive windows, transport, outdoor lightning, photovoltaic panels, solar panels, displays, eye glasses, airplane wings, radio-antennas, signal processing equipment, military equipment, textile clothing, thermoelectric generators units, air-conditioning units, refrigeration-units, portable vaccine cooler, medical-transport space-crafts, space instrumentation systems, nuclear-engines.

### EXAMPLES

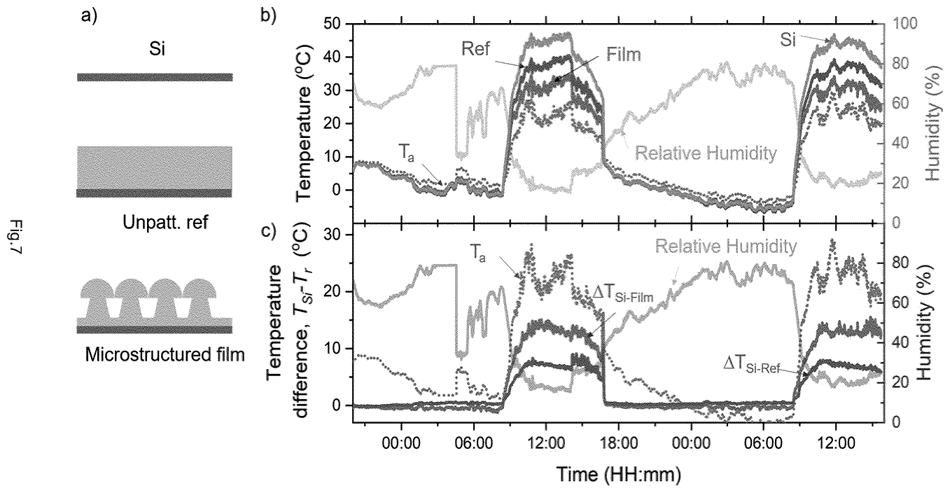

To experimentally test the radiative cooling effect of the microstructured film of the present disclosure, a specific experiment was designed, consisting of simultaneously measuring the temperature of a Si slab, T_{Si}, which is compared to the temperature of a Si slab coated with the reference unpatterned film of ORMOCOMP®, T_{ref}, and another Si wafer coated with the microstructured film of the present disclosure, T_{film}. The temperature measurement is performed by using 4-point resistive thermometers (PT100) attached to the backside of the Si substrates with silver paste to ensure an excellent thermal contact. The three embodiments faced the sky and during daylight hours they were exposed to direct sunlight. Standard 550 um-thick boron-doped Si wafers were used as substrates, as an example case, acting as solar absorbers. The experimental set-up and schematic illustrations of the studied samples and their configurations are shown in FIG. 6a and b, respectively.

The following Examples are offered for illustrative purposes only and are not intended to limit the scope of the present invention in any way.

### Example 1

A 44 h continuous temperature measurement that serves to demonstrate the radiative cooling effect of the mushroom-type microstructured film is shown in FIG. 7. The bare Si substrate heats up during daylight hours due to sunlight absorption, reaching a maximal temperature of 47.3 C at 1:45 pm. Both the reference and the microstructured film of the present disclosure (mushroom type for example) keep the Si substrate at lower temperature, particularly during daytime, compared to the bare Si substrate, demonstrating radiative cooling.

Since Ormocomp and the patterned film are highly transparent in the range from 400 nm to 800 nm, sunlight passes through and is absorbed by the Si substrate heating it up above the ambient. As shown in FIG. 4d, a broadband radiative cooler such as our microstructured film evacuates heat with a higher net power density as its temperature is much greater than the ambient, Tₐ−Tᵣ<<0. For that reason, the microstructure coating evacuates heat more efficiently from 10 am to 4 pm. FIG. 7c also shows that when the Si wafer is coated with the mushroom-type microstructured film, its temperature is lowered by an average of 13 degrees during daytime, as the system reaches its steady state operation temperature. In comparison, the unpatterned reference coating cools down the Si substrate by only 7 degrees.

This experiment demonstrates the radiative cooling efficiency of the film.

The measured relative humidity is plotted on the right axis. Although atmospheric water vapor reduces the atmospheric transmittance and therefore reduces the radiative cooling efficiency, here the oscillations in T_{Si}−Tᵣ are mostly due to temperature variations and not to the actual moisture content of the atmosphere. Relative humidity changes happen slowly with time, and thus it is assumed to not introduce changes in the thermal conductivity and dissipation properties of the metamaterial.

### Example 2

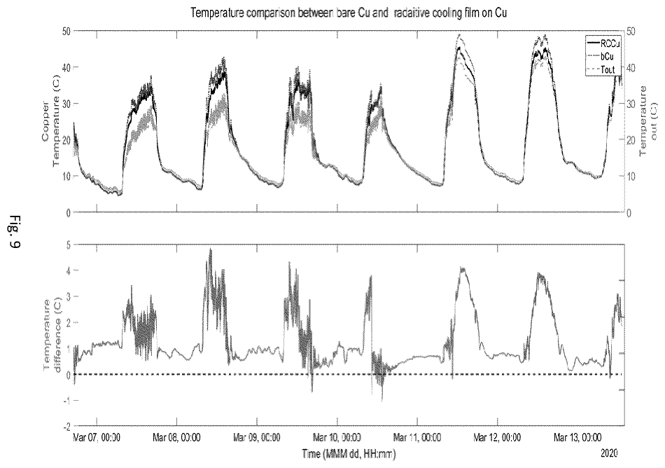

A measurement (similar to that included in Example 1) is performed on silver coated Si substrates (FIG. 8a). For this experimental configuration the unpatterned reference and the microstructured film cover the surface of the silver-coated Si substrate. The samples faced the sky during a clear day-and-night cycle and the results are plotted in FIG. 8b. When a silver-coated Si slab is covered with the patterned film and exposed to direct sunlight, average below-ambient radiative cooling at 2.5° C. is achieved, which means that particular structures can keep a surface 2.5° C. cooler than the ambient temperature, passively-without requiring electricity input or any other means of added energy. Furthermore, the silver coating reflects most of the incident solar radiation, thus lowering the temperature of the Si slab by 21.6 C in average, from 10:45 am and 12:45, when the system reaches a steady state temperature.

In addition to the passive radiative cooling a water repelling functionality is achievable allowing the surfaces to be self-cleaned. This is of particular interest for applications such as photovoltaic panels and building windows which require to have a clean surface for maximum performance.

### Example 3

To test the performance of our cooling film, another experiment was designed in which the temperature of a reference Copper slab, TCu, is compared to the temperature of an identical slab, covered with the radiative cooling film, TRCCu, both simultaneously exposed to direct sunlight. For this experiment, no additional heat input is introduced, besides sunlight absorption. Since the radiative cooling film is highly transparent in the visible wavelength range, during daylight hours the incoming sunlight is transmitted to the Cu slabs in similar amounts, heating them up above the ambient temperature.

The measurements were carried out at ICN2 (Bellaterra) and the weather conditions were variable, ranging from covered sky and high speed wind to clear and still conditions. From the 6 to the 11 March the slabs were exposed to the atmospheric conditions and from the 11 to the 13 of March they were covered with a convection shield (CS) made of Polymethylpentene (TPX) (FIG. 1b) which is highly transparent to visible light. The convection cover was put in place in order to emulate performance under the hardest weather conditions for solar heating: a completely clear and still sunny day.

The continuous temperature measurements from the 6^{th} to the 14^{th} of March of the reference Cu, and the Cu covered with the cooling film are shown in FIG. 9. A comparison of the temperature of both slabs as well as the measured outdoor temperature is shown in FIG. 9a. The outdoor temperature is measured with a PT100 located very close to the slabs, which stays covered as well when the TPX convection shield is installed to reduce the effect of the wind. The bottom panel shows the temperature difference between the reference and the slab covered with the radiative film.

A clear effect on cooling due to the radiative heat transfer is observed from the measurements. The maximum average temperature difference reached between the reference and the covered Cu slab, over 10:00 to 14:30 where the irradiance is nearly constant, is around 3.2° C. for low wind speeds (CS), with maximum values of ΔT=4.8° C. (w/o CS).

### Example 4

An experiment consisting on applying the micro-patterned film directly on a small commercial solar cell, and comparing its temperature to its thermal performance before being coated with the RC-micro-patterned film (FIG. 10) was designed. To account for possible changes on the monitored voltage and cell temperature induced by environmental conditions, five previously calibrated cells modules where analysed simultaneously. Interestingly, a 6% relative efficiency increase for the covered solar panel was measured (FIG. 10 (d)), compared to the uncovered cell (FIG. 10 (c)). The higher output voltage can be attributed to the RC effect of the film and to the fact that the pattern on it improves sunlight trapping. The experiment also showed a temperature decrease of the covered solar cell by an average 2° C. (FIG. 10b) compared to uncovered modules (FIG. 10a). This result is very significant considering that the conventional glass or polymeric covers in commercial PV modules already provide to some extent a RC cooling effect by the natural blackbody radiation properties of these materials.

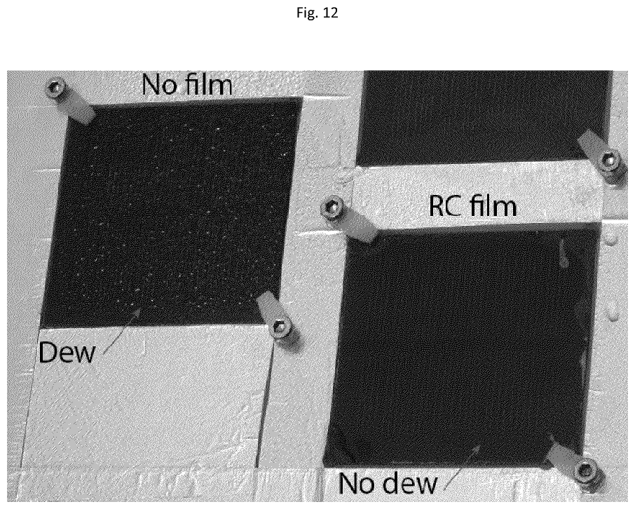

Moreover, during this experiment it was possible to observe that the micro-patterned film exhibits another interesting functionality: it has anti-dew and anti-frost properties, as shown in FIG. 12.

1. A microstructured film comprising inorganic-organic hybrid polymers, wherein the structure thereof is composed by repetitive elements having each one of the following shapes:
I) a shape which vertical cross-section is in the form of a 4-sided polygon in which an upper side and a lower side are parallel and have a different length;
II) a shape which vertical cross-section is a concave plane;
III) a shape which vertical cross-section is in the form of a 4-sided polygon in which an upper side and a lower side are parallel and have a different length,
and wherein the length of the lower side for shapes I) and III), or the length of a flat part of the concave plane in shape II) ranges from 0.1 μm to 20 μm,
and wherein a distance between each element in the film ranges from 1 μm to 20 μm,
and wherein a height of each element is lower than 7 μm.

2. A microstructured film consisting of inorganic-organic hybrid polymers, wherein the structure thereof is composed by repetitive elements having each one of the following shapes:
I) a shape which vertical cross-section is in the form of a 4-sided polygon in which an upper side and a lower side are parallel and have a different length;
II) a shape which vertical cross-section is a concave plane;
III) a shape which vertical cross-section is in the form of a 4-sided polygon in which an upper side and a lower side are parallel and have a different length,
and wherein the length of the lower side for shapes I) and III), or the length of a flat part of the concave plane in shape II) ranges from 0.1 μm to 20 μm,
and wherein a distance between each element in the film ranges from 1 μm to 20 μm,
and wherein a height of each element is lower than 7 μm.

3. The microstructured polymeric film according to claim 1, wherein said film is deposited over a carrier as a mechanical support.

4. The microstructured polymeric film according to claim 3, wherein said carrier is a transparent polymer.

5. The microstructured polymeric film according to claim 4, wherein said polymer is polymethylpentene, polyethylene or polyethylene terephthalate.

6. The microstructured film according to claim 1, wherein said inorganic-organic hybrid polymers comprise inorganic silicates with Si—O—Si linkages.

7. The microstructured film according to claim 6, wherein said inorganic-organic hybrid polymers comprising inorganic silicates with Si—O—Si linkages are Polyhedral Oligomeric SilSesquioxanes (POSS) or Organically Modified Ceramics.

8. A method for manufacturing a microstructured film according to claim 1, comprising the steps of:
a) contacting an inorganic-organic hybrid polymer with polydimethylsiloxane acting as a working stamp;
b) applying low pressure between 1 and 5 bar over the assembly obtained in step a) and exposing it to UV light for curing;
e) separating the polydimethylsiloxane from the cured inorganic-organic hybrid polymer, giving thereby the microstructured film.

9. The method for manufacturing a microstructured film according to claim 8, further comprising, before step a), the step of putting into contact a mechanically supporting carrier to said inorganic-organic hybrid polymer.

10. The method according to claim 8, wherein said inorganic-organic hybrid polymers comprise inorganic silicates with Si—O—Si linkages.

11. The method according to claim 10, wherein said inorganic-organic hybrid polymers comprising inorganic silicates with Si—O—Si linkages are Polyhedral Oligomeric SilSesquioxanes (POSS) or Organically Modified Ceramics.

12. A method for cooling the surface of a substrate, comprising the step of applying the microstructured film according to claim 1, with or without carrier, over said substrate, wherein the substrate is any material that suffers from heating and needs to be cooled down passively, by applying the microstructured film.

13. The method according to claim 12, wherein said substrate is selected from a metallic surface, silicon, solar cells, structural materials used in roofs and buildings, polymers or glass.

14. The method according to claim 12, wherein said microstructured film, without carrier, is directly applied over said substrate, wherein the film is then in direct contact with the substrate.

15. The method according to claim 12, wherein said microstructured film, with carrier, is applied over said substrate by means of a natural or synthetic adhesive, with a physical or chemical curing, wherein the adhesive is applied between the carrier and the substrate.

16. The method according to claim 12, wherein said substrate is located outdoors.

17. The method according to claim 12, wherein said substrate is located in traffic and mobility monitoring devices, agriculture irrigation controllers, glass or plastic greenhouse, windows, building facets, building windows, automotive windows, transport, outdoor lightning, photovoltaic panels, solar panels, displays, eye glasses, airplane wings, radio-antennas, signal processing equipment, military equipment, textile clothing, thermoelectric generators units, air-conditioning units, refrigeration-units, portable vaccine cooler, medical-transport space-crafts, space instrumentation systems, or nuclear-engines.

18. A substrate comprising the microstructured film according to claim 1.

19. The substrate according to claim 18, which is located outdoors.

20. The substrate according to claim 18, which is located in traffic and mobility monitoring devices, agriculture irrigation controllers, glass or plastic greenhouse, windows, building facets, building windows, automotive windows, transport, outdoor lightning, photovoltaic panels, solar panels, displays, eye glasses, airplane wings, radio-antennas, signal processing equipment, military equipment, textile clothing, thermoelectric generators units, air-conditioning units, refrigeration-units, portable vaccine cooler, medical-transport space-crafts, space instrumentation systems, or nuclear-engines.
